(19) United States
(12) Patent Application Publication
(10) Pub. No.: US 2020/0411612 A1
(43) Pub. Date: Dec. 31, 2020

(54) ELECTROLUMINESCENT DEVICE

(71) Applicant: TCL China Star Optoelectronics Technology Co., Ltd., Shenzhen, Guangdong (CN)

(72) Inventors: Aiguo TU, Shenzhen, Guangdong (CN); Jinchuan Li, Shenzhen, Guangdong (CN); Yuanchun WU, Shenzhen, Guangdong (CN); Poyen LU, Shenzhen, Guangdong (CN)

(21) Appl. No.: 16/617,839

(22) PCT Filed: Jul. 17, 2019
(86) PCT No.: PCT/CN2019/096271

§ 371 Date: Nov. 27, 2019

(30) Foreign Application Priority Data
Jun. 21, 2019 (CN) 201910543313.4

(51) Int. Cl. H01L 27/32

(52) U.S. Cl. CPC H01L 27/3246; H01L 27/322

(57) ABSTRACT

An electroluminescent device is provided, which the electroluminescent device includes a black photoresist disposed in a pixel definition layer. Optical performance of the electroluminescent device is improved by increasing the black photoresist between the pixel and the pixel, thereby improving the chromaticity viewing angle of pictures mainly composed of red light and/or green light.

### FIELD OF INVENTION

The present invention relates to the field of display technologies, and in particular, to an electroluminescent device.

### BACKGROUND OF INVENTION

OLED (English full name: organic light-emitting diode, referred to as OLED) devices are also known as organic electro-laser devices and organic light-emitting semiconductors. Basic structure of an OLED is a sandwich-like structure that connects a positive electrode of electricity to a thin and transparent indium tin oxide (ITO) having semiconductor characteristics, where a metal-faced cathode is packaged into therebetween. The entire structural layer includes a hole transport layer (HTL), a light-emitting layer (EL), and an electron transport layer (ETL). When the power is supplied to an appropriate voltage, the positive hole and the charge faced to the cathode are combined in the light-emitting layer, and under the action of Coulomb force, the excitons (electron-hole pairs) in an excited state are combined at a certain probability, and this excited state is unstable in the normal environment. Excited state excitons recombine and transfer energy to the luminescent material, causing it to transit the energy level from ground state to the excited state. The excited state energy generates photons through the radiation process, which releases photon energy and generates light, and red, green, and blue RGB three primary colors are generated according to a light formula, so that basic colors are formed.

First, the OLEDs have self-illuminating characteristics. Unlike thin film transistor-liquid crystal displays (TFT-LCDs), which require a backlight, therefore visibility and brightness are high. Secondly, the OLEDs have advantages of low voltage demand, high power saving efficiency, fast response times, light weight, thin thickness, simple structure, low cost, wide viewing angles, almost infinite contrast ratio, low power consumption, and high reaction speed, and have become one of the most important display technologies. It is gradually replacing TFT-LCD, and it is expected to become the next generation mainstream display technology after the LCD.

In current large-size OLED devices, in order to achieve 8K resolution, a bottom device has a decrease in aperture ratio due to an increase in a number of TFTs, and lifetime of the OLED devices are reduced to about two-thirds of that of the 4K OLED TV. In order to improve the lifetime of 8K large-size OLED displays, use of inkjet printing technology is an important development direction.

### Technical Problem

Large-size OLED devices, especially those made by inkjet printing technology, have a micro-cavity effect due to a thin metal in the transparent cathode, and device efficiency and color fluctuate greatly with a thickness of an organic material layer. Generally, a color filter encapsulation cover is used to improve color uniformity, and a black photoresist is used between the color filters to reduce lateral leakage of pixels to improve lateral viewing angle. However, when a blue light with large-angle is incident on a green color filter (take the vertical direction of the panel as the normal), color purity of the green light is lowered, the color gamut is reduced, and chromaticity of pictures mainly composed of red light and/or green light is caused. Therefore, there is a need to find a new type of electroluminescent device to solve the above problems.

### SUMMARY OF INVENTION

### Technical Solution

An object of the present invention is to provide an electroluminescence device which is capable of improving phenomenon of a chromaticity viewing angle of pictures mainly composed of red light and/or green light existing in the current electroluminescent device.

In order to solve the above problems, an embodiment of the present invention provides an electroluminescence device including: a substrate; a thin film transistor disposed on the substrate; a planarization layer disposed on the thin film transistor; anodes space apart from each other and disposed on the planarization layer; first pixel definition layers disposed on the planarization layer between two adjacent anodes; and a black photoresist disposed in the first pixel definition layer.

Further, the anode includes a main part and two side parts, wherein the two side parts extend laterally into the first pixel definition layers.

Further, a side part of the black photoresist is further disposed on the side part of the anode.

Further, a shape of the black photoresist corresponds to a shape of the first pixel definition layer.

Further, the shape of the black photoresist is trapezoid.

Further, a thickness of the black photoresist ranges from 1 μm to 5 μm.

Further, the electroluminescent device further including an encapsulation cover disposed on the first pixel definition layers.

Further, the encapsulation cover includes one of a transparent cover or a color filter cover.

Further, the electroluminescent device further including second pixel definition layers disposed on the first pixel definition layers.

Further, the black photoresist is disposed between the first pixel definition layer and the second pixel definition layer.

### Beneficial Effect

The present invention relates to an electroluminescent device wherein the electroluminescent device includes a black photoresist disposed in pixel definition layer. The invention improves optical performance of the electroluminescent devices by increasing the black photoresists between the pixels and the pixels, thereby improving the chromaticity viewing angle of the green-based picture and the red-based picture.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural diagram showing an electroluminescent device according to a first embodiment of the present invention.

FIG. 2 is a schematic structural diagram showing an electroluminescent device according to a second embodiment of the present invention.

FIG. 3 is a schematic structural diagram showing an electroluminescent device according to a third embodiment of the present invention.

FIG. 4 is a schematic structural diagram showing an electroluminescent device according to a fourth embodiment of the present invention.

The parts in the figures are identified as follows:
100, electroluminescent device; 1, substrate;
2, thin film transistor; 3, planarization layer;
4, anode; 5, first pixel definition layer;
6, black photoresist; 7, hole injection layer;
8, hole transport layer; 9, light-emitting layer;
10, electron transport layer; 11, electron injection layer;
12, cathode; 13, encapsulation cover;
14, second pixel definition layer;
41, main part; 42, side part.

### DETAILED DESCRIPTION OF EMBODIMENTS

The preferred embodiments of the present invention are described in detail below with reference to the accompanying drawings. The invention can be implemented by way of example, the technical content of the present disclosure will become more apparent, so that those skilled in the art will understand how to implement the invention. The present invention may, however, be embodied in many different forms and embodiments, and the scope of the invention is not limited to the embodiments described herein.

Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention.

In the drawings, components having similar structures are denoted by the same numerals. Moreover, the size and thickness of each component shown in the drawings are arbitrarily shown for ease of understanding and description, and the invention does not limit the size and thickness of each component.

When a component is described as “on” another component, the component can be placed directly on the other component; there can also be an intermediate component that is placed on the component, and the intermediate component is placed on another component. When a component is described as “installed to” or “connected to” another component, it can be understood as directly “installed to” or “connected to”, or a component is “installed to” or “connected to” another component through an intermediate component.

### First Embodiment

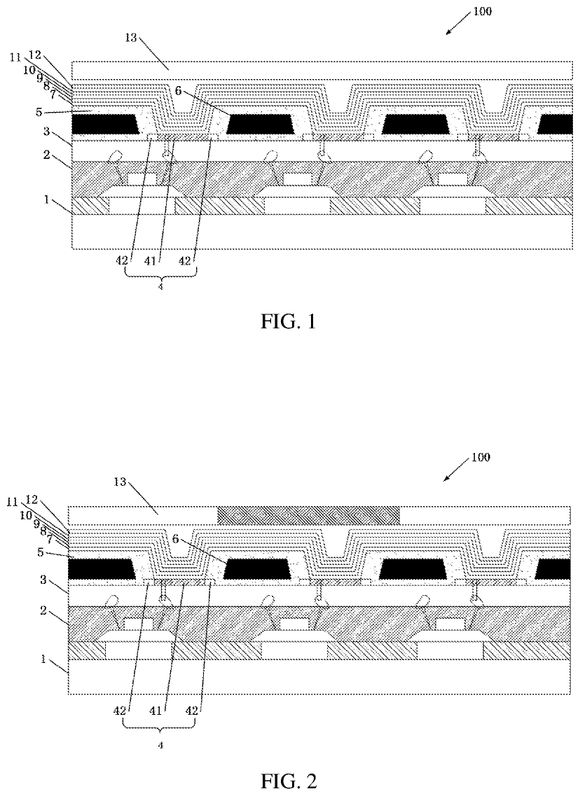

As shown in FIG. 1, where an electroluminescent device 100 includes: a substrate 1, a thin film transistor 2, a planarization layer 3, an anode 4, a first pixel definition layer 5, a black photoresist 6, a hole injecting layer 7, a hole transport layer 8, a light-emitting layer 9, an electron transport layer 10, an electron injection layer 11, a cathode 12, and an encapsulation cover 13.

The substrate 1 can be coated on a clean glass substrate by a PI (English: polyimide film; polyimide) coater and processed by a high temperature curing process. Since the PI film has excellent high and low temperature resistance, electrical insulation, adhesion, radiation resistance, and dielectric resistance, the substrate 1 thus produced has good flexibility.

The thin film transistor 2 is disposed on the substrate 1; the planarization layer 3 is disposed on the thin film transistor 2; the thin film transistor 2 and the planarization layer 3 are provided with a gate, a source, and a drain. When a positive voltage is applied to the gate, an electric field is generated between the gate and a semiconductor layer of the thin film transistor. Under this electric field, an electron path is formed to form a conduction state between the source and the drain. The larger the voltage applied to the gate, the more electrons are attracted, so a conductive current is larger. When a negative voltage is applied to the gate, a closed state is formed between the source and the drain.

The anodes 4 are space apart from each other and disposed on the planarization layer 3 and the first pixel definition layers 5 are disposed on the planarization layer 3 between two adjacent anodes 4. The anode 4 includes a main part 41 and two side parts 42, wherein the side parts 42 of the anode 4 extend laterally into the first pixel definition layers 5.

The black photoresist 6 can be disposed only in the first pixel definition layer 5, or can be extended on the side part 42 of the anode 4. The black photoresist 6 described in this embodiment is disposed in the first pixel definition layer 5. Optical performance of the electroluminescent device 100 is improved by adding a black photoresist 6 between the pixels and the pixels, thereby improving chromaticity viewing angle of pictures mainly composed of red light and/or green light.

There are two or more black photoresists 6. Specifically, they can be disposed on the anodes between any pixel and the pixel to reduce the color gamut and improve optical performance of the electroluminescent devices 100.

A shape of the black photoresist 6 corresponds to a shape of the first pixel definition layer 5. Specifically, it can be a trapezoid as shown in the figure.

Due to the current production process level, a thickness of the black photoresist 6 ranges from 1 μm to 5 μm.

The hole injection layer 7 is disposed on the anode 4; the hole transport layer 8 is disposed on the hole injection layer 7; the light-emitting layer 9 is disposed on the hole transport layer 8; the electron transport layer 10 is disposed on the light-emitting layer 9; the electron injection layer 11 is disposed on the electron transport layer 10; and the cathode 12 is disposed on the electron injection layer 10. The hole transport layer 8 controls the transmission of holes, thereby controlling the recombination of holes with electrons in the light-emitting layer, thereby improving the luminous efficiency.

The hole injection layer 8, the hole transport layer 9, and the light-emitting layer 10 can be formed by an inkjet printing technique.

The electron transport layer 10 includes an inorganic layer, an organic layer, or one or more of a combination of the inorganic layer and the organic layer. The electron transport layer 10 controls the transmission of electrons, thereby controlling the recombination of electrons with holes in the light-emitting layer, thereby improving the luminous efficiency.

The encapsulation cover 13 is disposed on the cathode 12. The encapsulation cover 13 includes one of a transparent cover or a color filter cover. The encapsulation cover used in this embodiment is a transparent cover. In this way, the effect of blocking the invasion of water and oxygen is achieved, and lifetime of the electroluminescent device 100 is improved.

### Second Embodiment

Only the differences between the present embodiment and the first embodiment will be described below, and the same portions will not be described herein.

As shown in FIG. 2, where the encapsulation cover 13 is disposed on the cathode 12. The encapsulation cover 13 includes one of a transparent cover or a color filter cover. The encapsulation cover used in this embodiment is a color filter cover. On the one hand, in order to achieve the effect of blocking the invasion of water and oxygen, the lifetime of the electroluminescent device 100 is improved. On the other hand, the color filter cover is used to as the encapsulation cover to improve the color uniformity, and a black photoresist is used between the color filter covers to reduce lateral light leakage of the pixels to improve the lateral viewing angle.

### Third Embodiment

Only the differences between the present embodiment and the first embodiment will be described below, and the same portions will not be described herein.

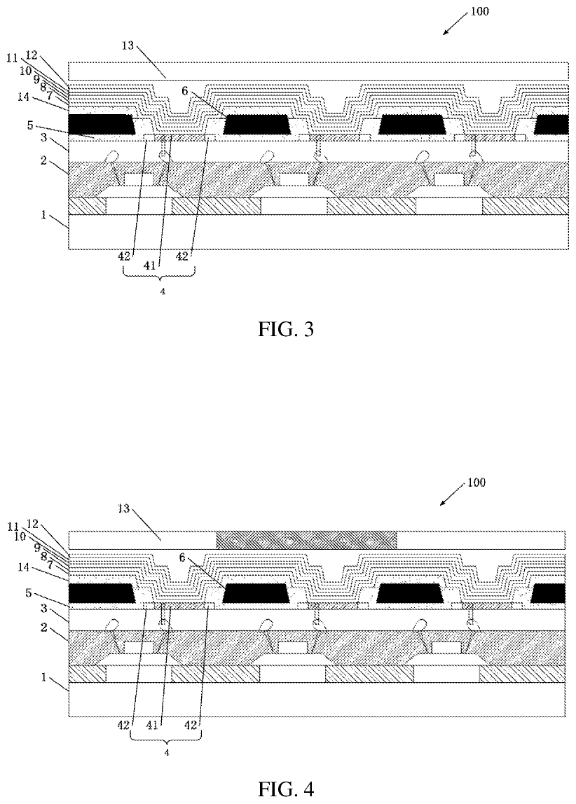

As shown in FIG. 3, where the electroluminescent device 100 further includes second pixel definition layers 14 disposed on the first pixel definition layers 5, the black photoresist 6 is disposed between the first pixel definition layer 5 and the second pixel definition layer 14. Specifically, the second pixel definition layers 14 are formed by a half-etching mask and a half-etching exposure process. Thereby, film flatness of the electroluminescence device 100 can be improved.

### Fourth Embodiment

Only the differences between the present embodiment and the second embodiment will be described below, and the same portions will not be described herein.

As shown in FIG. 4, where the electroluminescent device 100 further includes second pixel definition layers 14 disposed on the first pixel definition layers 5, the black photoresist 6 is disposed between the first pixel definition layer 5 and the second pixel definition layer 14. Specifically, the second pixel definition layers 14 are formed by a half-etching mask and a half-etching exposure process. Thereby, film flatness of the electroluminescence device 100 can be improved.

The electroluminescent device provided by the present invention has been described in detail above. It is understood that the exemplary embodiments described herein are to be considered as illustrative only, and are not intended to limit the invention. Descriptions of features or aspects in each exemplary embodiment should generally be considered as suitable features or aspects in other exemplary embodiments. While the invention has been described with reference to the preferred embodiments thereof, various modifications and changes can be made by those skilled in the art. The present invention is intended to cover such modifications and variations within the scope of the appended claims, and any modifications, equivalents, and modifications within the spirit and scope of the present invention are intended to be included within the scope of the present invention.

What is claimed is:

1. An electroluminescent device, comprising:
a substrate;
a thin film transistor disposed on the substrate;
a planarization layer disposed on the thin film transistor;
anodes space apart from each other and disposed on the planarization layer;
first pixel definition layers disposed on the planarization layer between two adjacent anodes; and
a black photoresist disposed in the first pixel definition layer.

2. The electroluminescent device according to claim 1, wherein the anode comprises a main part and two side parts, wherein the two side parts extend laterally into the first pixel definition layers.

3. The electroluminescent device according to claim 2, wherein a side part of the black photoresist is further disposed on the side part of the anode.

4. The electroluminescent device according to claim 1, wherein a shape of the black photoresist corresponds to a shape of the first pixel definition layer.

5. The electroluminescent device according to claim 4, wherein the shape of the black photoresist is trapezoid.

6. The electroluminescent device according to claim 1, wherein a thickness of the black photoresist ranges from 1 μm to 5 μm.

7. The electroluminescent device of claim 1, further comprising an encapsulation cover disposed on the first pixel definition layers.

8. The electroluminescent device according to claim 7, wherein the encapsulation cover comprises one of a transparent cover or a color filter cover.

9. The electroluminescent device according to claim 1, further comprising second pixel definition layers disposed on the first pixel definition layers.

10. The electroluminescent device according to claim 9, wherein the black photoresist is disposed between the first pixel definition layer and the second pixel definition layer.
